(19) United States
(12) Patent Application Publication
(10) Pub. No.: US 2026/0095168 A1
(43) Pub. Date: Apr. 2, 2026

(54) Timing Management in Serial Data Interfaces

(71) Applicant: Super Micro Computer, Inc., San Jose, CA (US)

(72) Inventor: Ronghua Wu, San Jose, CA (US)

(21) Appl. No.: 18/903,974

(22) Filed: Oct. 1, 2024

(51) Int. Cl. H03K 5/156; G06F 1/08; G06F 1/12

(52) U.S. Cl. CPC H03K 5/1565; G06F 1/08; G06F 1/12

(57) ABSTRACT

This application is directed to managing signal timing on a serial data interface of an electronic device. The electronic device includes an interface controller configured to drive an output interface. The interface controller receives a first clock signal, and determines a low cycle length of the first clock signal. The interface controller dynamically determines a duty cycle of a second clock signal based on the low cycle length of the first clock signal. The second clock signal having the duty cycle is generated by the interface controller, and provided to the output interface. In some embodiments, the interface controller determines an outgoing delay, an incoming delay, and a sampling tolerance time. A difference may be further determined between the low cycle length of the first clock signal and a sum of the incoming delay and the outgoing delay, and applied to control the duty cycle of the second clock signal.

### TECHNICAL FIELD

This application relates generally to electronic circuit including, but not limited to, methods, apparatuses, structures, devices, and systems for managing signal timing on a serial output interface of an electronic device or system (e.g., disposed in a server rack).

### BACKGROUND

An electronic device is oftentimes coupled with a peripheral device via a serial data bus wherein one potential issue that can arise is clock-data misalignment due to signal latency. In serial communication, data bits are transmitted sequentially, and any delay in the signal can lead to a receiving device interpreting the data incorrectly. If the clock signal, which governs the timing of data sampling, is not synchronized with an incoming data stream, bits may be read too early or too late, resulting in misinterpretation of transmitted information. This misalignment can be exacerbated by factors such as cable length, interference, interruption by intermediate modules, and variations in processing speed between the devices. As a result, errors may occur in data transmission, leading to corrupted information, system instability, or even complete communication failure. Properly managing signal integrity and ensuring precise synchronization between the clock and data signals is crucial for maintaining effective communication in these setups.

### SUMMARY

Various embodiments of this application are directed to methods, apparatuses, structures, devices, and systems for controlling temporal alignment of a clock signal and an incoming data stream of a processor of an electronic device. In accordance with some embodiments of this application disclosed herein is the realization that precise synchronization between the clock and data signals may be lost for a first clock signal of the processor of the electronic device and an incoming data stream that is provided by a peripheral device coupled to the electronic device. In some situations, the incoming data stream is generated by the peripheral device based on a second clock signal, which is derived from the first clock signal and provided to the peripheral device with a clock latency. The incoming data stream has a temporal shift with respect to the first clock signal. The temporal shift includes both the clock latency and its own data latency caused by a signal path coupling an output of the peripheral device to an input of the processor of the electronic device. Particularly, in some situations, the signal path includes an interface controller (e.g., a complex programmable logic device (CPLD), a field programmable gate arrays (FPGAs) device), which may contribute to both the clock latency and the data latency. In some implementations, the interface controller is configured to control synchronization of the first clock signal and the incoming data stream by controlling the second clock signal that is provided to the peripheral device. The interface controller may compensate for the clock latency or the data latency in part or entirely, thereby allowing the processor of the electronic device to process the incoming data stream properly based on the first clock signal with no impact or a tolerable impact of the clock latency or the data latency.

In one aspect, some implementations include a method for managing signal timing for an electronic device (e.g., a server computer). The method is implemented at an interface controller coupled to, and configured to drive, a serial output interface of the electronic device. The method includes receiving a first clock signal, determining a low cycle length of the first clock signal, dynamically determining a duty cycle of a second clock signal based on the low cycle length of the first clock signal, and generating the second clock signal having the duty cycle (e.g., without any change of the duty cycle of the second clock signal, by moving an edge of the second clock signal by a temporal change).

In some implementations, determining the low cycle length of the first clock signal further includes determining a period and a duty cycle of the first clock signal. The low cycle length of the first clock signal is determined based on the period and the duty cycle of the first clock signal.

In some embodiments, the method further includes determining an outgoing delay and an incoming delay of the interface controller, and the duty cycle of the second clock signal is determined based on a sum of the outgoing delay and the incoming delay of the interface controller.

In some embodiments, the method further includes determining a sampling tolerance time of a host processor. The interface controller is configured to be coupled between the host processor and the serial output interface. The sampling tolerance time defines a temporal length limit between edges of a host incoming serial signal and the first clock signal of the host processor. The duty cycle of the second clock signal is determined based on the sampling tolerance time.

In another aspect, some implementations include an electronic device (e.g., a server computer). The electronic device includes a host processor configured to provide a first clock signal and processing a host incoming serial signal, an interface controller coupled to the host processor, and a serial output interface coupled to the interface controller. The interface controller is configured to receive the first clock signal, determine a low cycle length of the first clock signal, dynamically determine a duty cycle of a second clock signal based on the low cycle length of the first clock signal, and generate the second clock signal having the duty cycle. The serial output interface is configured to couple to a peripheral device and provide the second clock signal to the peripheral device.

In yet another aspect, some implementations include a non-transitory computer-readable storage medium storing one or more programs for execution by an interface controller. The interface controller is configured to drive a serial output interface of an electronic device. The one or more programs further comprising includes for receiving a first clock signal, determining a low cycle length of the first clock signal, dynamically determining a duty cycle of a second clock signal based on the low cycle length of the first clock signal, and generating the second clock signal having the duty cycle.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a front view of an example server rack that supports one or more servers, in accordance with some embodiments.

FIG. 2 is a block diagram of an example system module in a typical electronic device, which may be applied as a server in FIG. 1, in accordance with some embodiments.

FIG. 3A is a block diagram of an example electronic device including an interface controller coupled at a serial output interface, in accordance with some embodiments.

FIG. 3B is a temporal diagram of a set of sample signals including a first clock signal, a host outgoing serial signal, and a periphery incoming serial signal, in accordance with some embodiments.

FIG. 4 is a temporal diagram of a plurality of example signals measured at an output of a host processor or a first controller of an electronic device and an input of a peripheral device, in accordance with some embodiments.

FIG. 5 is a temporal diagram illustrating a plurality of example compensation schemes associated with a duty cycle of a second clock signal, in accordance with some embodiments.

FIG. 6 is a temporal diagram illustrating another example compensation scheme applied to modify a duty cycle of a second clock signal, in accordance with some embodiments.

FIG. 7 is a flow diagram of an example method for managing signal timing on a serial output interface of an electronic device (e.g., a server in FIG. 1), in accordance with some embodiments.

Like reference numerals refer to corresponding parts throughout the several views of the drawings.

### DETAILED DESCRIPTION

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details.

Various embodiments of this application are directed to methods, apparatuses, structures, devices, and systems for controlling temporal alignment of a clock signal and an incoming data stream of a host processor of an electronic device (e.g., a server 120). In accordance with some embodiments of this application disclosed herein is the realization that precise synchronization between the clock and data signals may be lost for a first clock signal of the host processor of the electronic device and an incoming data stream that is provided by a peripheral device coupled to the electronic device. The electronic device includes a serial output interface and an interface controller, which is coupled to, and configured to drive, the serial output interface of the electronic device. The interface controller receives a first clock signal, e.g., from the host processor of the electronic device, determines a low cycle length of the first clock signal, dynamically determines a duty cycle of a second clock signal based on the low cycle length of the first clock signal, and generates the second clock signal having the duty cycle. The duty cycle of the second clock signal is controlled to compensate for a clock latency or a data latency in part or entirely, such that the first clock signal of the host processor of the electronic device can be synchronized with an incoming data stream, which is provided by the peripheral device based on the second clock signal.

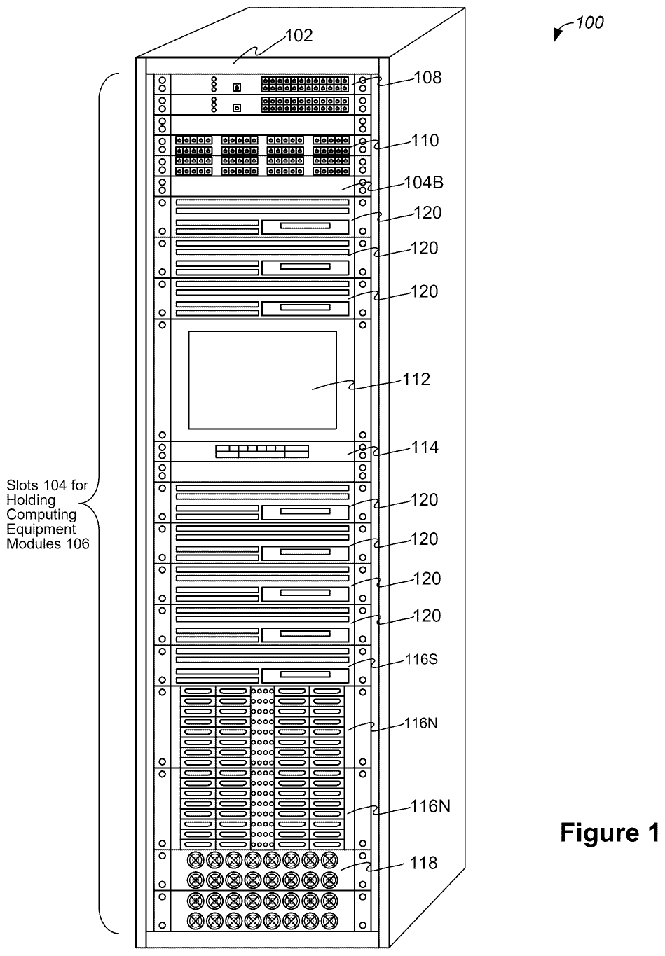

FIG. 1 is a front view of an example server rack 100 (also known as a rack mount, a rack cabinet, or simply a rack) that supports one or more servers 120, in accordance with some embodiments. The server rack 100 includes a frame 102 and a plurality of slots 104, and may be used in a data center, a server room, or a network closet for supporting, organizing, and managing a plurality of computing equipment modules 106 (e.g., servers 120, storage devices 116S and 116N, networking equipment, and other types of hardware). Each of the plurality of slots 104 of the server rack 100 is configured to receive and support a respective computing equipment module 106. In some embodiments, the plurality of slots 104 include at least one blank slot 104B that is not used to provide mechanical support to any equipment module 106 and can receive an equipment module 106 if needed. In some implementations, the server rack 100 has a predefined width of 19 or 23 inches, a height up to 84 inches or more, and a depth selected from 24, 32, 40, or 48 inches.

Examples of the computing equipment modules 106 supported by the plurality of slots 104 of the server rack 100 include, but are not limited to, a firewall module 108, a switch box 110, a server 120, a display device 112, a keyboard 114, a solid-state drive (SSD) 116S, a network-attached storage 116N, and an uninterruptible power supply (UPS) 118. Each computing equipment module 106 plays a respective role in maintaining a network and computing environment. In some embodiments, a firewall module 108 is a network security device that monitors and controls incoming and outgoing network traffic based on predetermined security rules, thereby establishing a barrier between a trusted internal network and untrusted external networks. The firewall module 108 may be placed near a network ingress point to protect the server rack 100 from unauthorized access, malware, and cyberattacks. In some embodiments, the firewall module 108 includes packet filtering, stateful inspection, VPN support, and intrusion prevention systems (IPS). In some embodiments, a switch box 110 is placed near the network ingress point jointly with the firewall module 108, and configured to receive incoming signals and forward the incoming signals (e.g., which may be converted to electrical signals) to different servers 120 mounted on the server rack 100. The switch box 110 is applied in the server rack 100 to minimize cable length and ensure efficient network traffic management. The switch box 110 may support different speeds (e.g., 800 gigabits per second (Gbps), 1.6 Tbs, 3.2 Tbs), have multiple ports (24, 48, etc.), and offer features like virtual local area network (VLAN) support, PoE (Power over Ethernet), and managed or unmanaged capabilities.

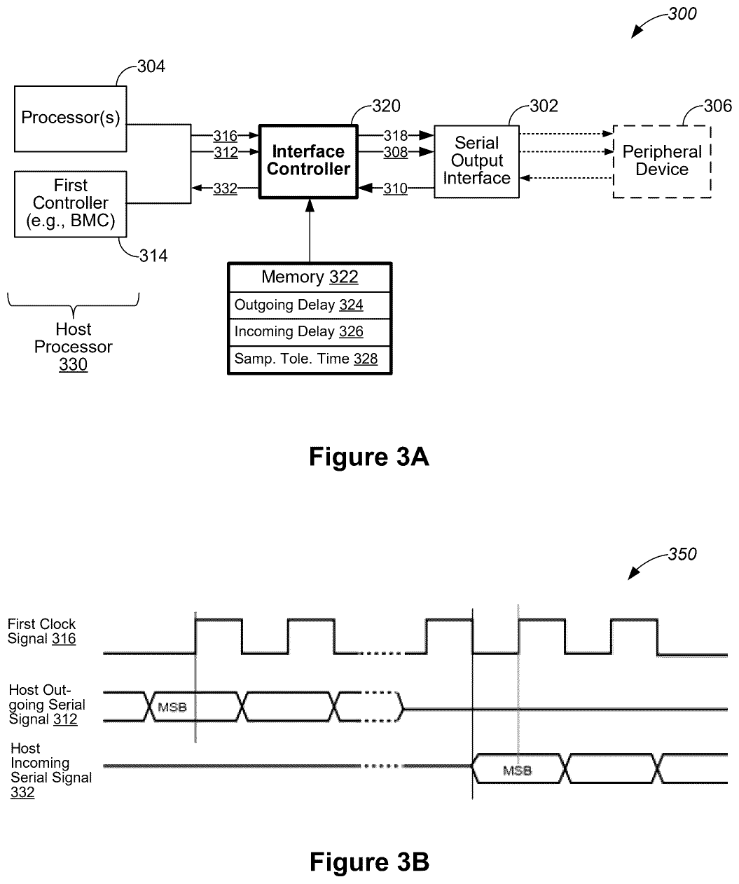

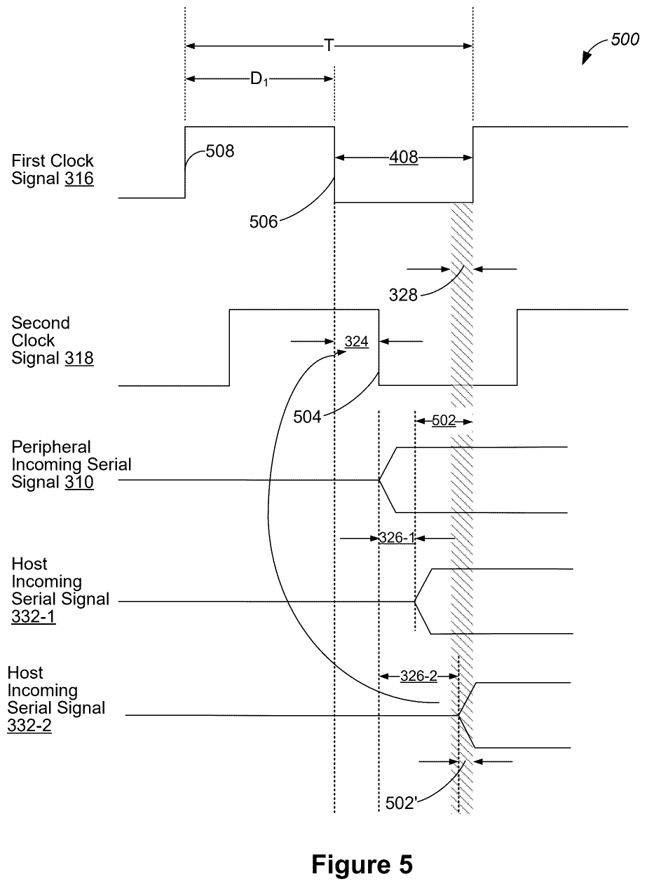

The plurality of computing equipment modules 106 of the server rack 100 may include a plurality of servers 120 each of which is configured to provides data, resources, services, or programs to other client devices over one or more wired or wireless communication networks. Each server 120 is mounted in a slot 104 of the server rack 100 and configured to provide one or more services (e.g., web hosting, database management, and application support). The servers 120, mounted on the server rack 100, may provide higher processing power, large memory capacity, redundant power supplies, and hot-swappable components for high availability and reliability compared with individual client devices. In some embodiments, the one or more rack servers 120 include a plurality of graphics processing units (GPU) configured to implement machine learning operations, e.g., in a data center associated with machine learning tasks. In some embodiments, the server 120 includes one or more processors, memory storing one or more programs for execution by the one or more processors, and a system housing for enclosing the one or more processors, the memory, and a power supply component (e.g., a PSU 216 in FIGS. 3A, 3B, and 5).

The SSD 116S and the network-attached storage 116N are configured to provide storage space for the servers 120 installed in the server rack 100. The SSD uses flash memory to store data and shows high speed, low latency, durability, and lower power consumption, and diverse capacities and form factors compared to hard drive devices (HDDs). Conversely, the network-attached storage (NAS) 116N is a dedicated file storage device that provides data access to a network and allows a large number of different types of client devices to retrieve data from centralized disk capacity. In some embodiments, the network-attached storage 116N may have a high capacity, redundant array of independent disks (RAID), support for a plurality of file-sharing protocols (NFS, SMB/CIFS, FTP), user management, and backup features. In some embodiments, the SSDs 116S are storage drives for speed, and for example, used within the servers 120 disposed on the same server rack 100, while the NAS 116N is configured for file sharing, data backup, and remote access.

In some implementations, the UPS 118 is applied to provide emergency power to other computing equipment modules 106 in case of a power outage, allowing them to remain operational long enough to safely shut down or switch to an alternative power source. In an example, the UPS 118 is mounted in the server rack 100 or placed on a bottom slot to support the weight, providing backup power to other computing equipment modules 106. The UPS 118 provides one or more of battery backup, surge protection, voltage regulation, real-time monitoring, management software, and/or varying runtimes based on capacity and load.

The server rack 100 further includes a plurality of mechanical structures configured to provide mechanical support, or facilitate access, to the plurality of computing equipment modules 106. The plurality of mechanical structures include one or more of: an open frame rack (e.g., having no door or side panel), mounting rails, cable management features (e.g., arms, hooks, and trays), power strips, shelves, drawers, and blanking panels. In some embodiments, the plurality of mechanical structures also includes a rack enclosure (e.g. cabinet), lockable doors, and side panels to protect the computing equipment modules 106 from unauthorized access. In an example, the server rack 100 includes, or is coupled to, a plurality of panels configured to convert the server rack 100 to a server cabinet. In some embodiments, the server rack 100 further includes a cooling system or a ventilation system to facilitate heat dissipation. Using a server rack 100 helps optimize space, improve cooling efficiency, simplify maintenance, and enhance the overall organization and management of information technology (IT) infrastructure.

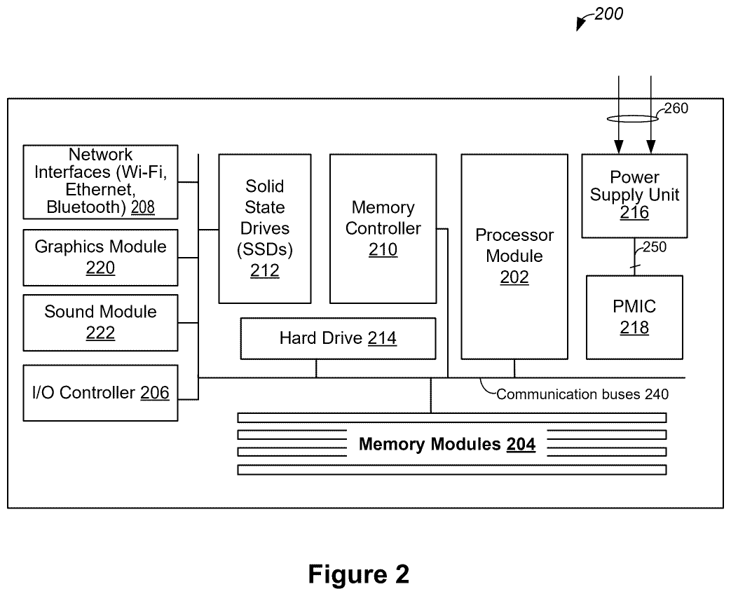

FIG. 2 is a block diagram of an example system module 200 in a typical electronic device, which may be applied as a server 120 in FIG. 1, in accordance with some embodiments. The system module 200 in this electronic device includes at least a processor module 202, memory modules 204 for storing programs, instructions and data, an input/output (I/O) controller 206, one or more communication interfaces such as network interfaces 208, and one or more communication buses 240 for interconnecting these components. In some embodiments, the I/O controller 206 allows the processor module 202 to communicate with an I/O device (e.g., a keyboard, a mouse or a track-pad) via a universal serial bus interface. In some embodiments, the network interfaces 208 includes one or more interfaces for Wi-Fi, Ethernet and Bluetooth networks, each allowing the electronic device to exchange data with an external source, e.g., a server or another electronic device. In some embodiments, the communication buses 240 include circuitry (sometimes called a chipset) that interconnects and controls communications among various system components included in system module 200.

In some embodiments, the memory modules 204 include high-speed random-access memory, such as DRAM, static random-access memory (SRAM), double data rate (DDR) dynamic random-access memory (RAM), or other random-access solid state memory devices. In some embodiments, the memory modules 204 include non-volatile memory, such as one or more magnetic disk storage devices, optical disk storage devices, flash memory devices, or other non-volatile solid state storage devices. In some embodiments, the memory modules 204, or alternatively the non-volatile memory device(s) within the memory modules 204, include a non-transitory computer readable storage medium. In some embodiments, memory slots are reserved on the system module 200 for receiving the memory modules 204. Once inserted into the memory slots, the memory modules 204 are integrated into the system module 200.

In some embodiments, the system module 200 further includes one or more components selected from a memory controller 210, solid state drives (SSDs) 212, a hard disk drive (HDD) 214, a power supply unit (PSU) 216, power management integrated circuit (PMIC) 218, a graphics module 220, and a sound module 222. The memory controller 210 is configured to control communication between the processor module 202 and memory components, including the memory modules 204, in the electronic device. The SSDs 212 are configured to apply integrated circuit assemblies to store data in the electronic device, and in many embodiments, are based on NAND or NOR memory configurations. The HDD 214 is a conventional data storage device used for storing and retrieving digital information based on electromechanical magnetic disks. The PSU 216 is configured to receive a plurality of power supply signals 260 and provide a plurality of DC power supplies 250 (e.g., 12V, 54V). The PMIC 218 is configured to modulate the plurality of DC power supplies 250 to other desired DC voltage levels, e.g., 5V, 3.3V or 1.8V, as required by various components or circuits (e.g., the processor module 202) within the electronic device. The graphics module 220 is configured to generate a feed of output images to one or more display devices according to their desirable image/video formats. The sound module 222 is configured to facilitate the input and output of audio signals to and from the electronic device under control of computer programs.

It is noted that communication buses 240 also interconnect and control communications among various system components including components 210-222.

FIG. 3A is a block diagram of an example electronic device 300 including an interface controller 320 coupled at a serial output interface 302, in accordance with some embodiments. An example of the electronic device 300 is a server 120 disposed on a server rack 100. The electronic device 300 includes one or more processors 304 (e.g., of a processor module 202 in FIG. 2), a serial output interface 302, and an interface controller 320. The of the one or more processors 304 coupled to the interface controller 320. Examples of the one or more processors 304 include, but are not limited to, a central processing units (CPU), a graphics processing unit (GPU), a tensor processing unit (TPU), a mobile processor, multi-core processors, a quantum processor, and a digital signal processor (DSP). In some embodiments, the electronic device 300 further includes a first controller 314, which is also coupled to the serial output interface 302. In some embodiments, the electronic device 300 is coupled to a peripheral device 306 via the serial output interface 302, and configured to provide a clock signal and an outgoing serial signal 308 to the peripheral device 306 and receive a periphery incoming serial signal 310 from the peripheral device 306. In an example, the peripheral device 306 includes a flash memory device (e.g., a NAND=based or NOR-based flash memory), and the serial output interface 302 of the electronic device 300 is mechanically and electrically coupled to the flash memory device. The clock signal and the outgoing serial signal 308 are provided to the flash memory device via the serial output interface 302.

In some embodiments, a host device 330 includes one or more processors 304, the first controller 314, or both. The interface controller 320 is coupled between the host device 330 and the serial output interface 302, and configured to drive the serial output interface 302 to facilitate data communication between the host device 330 and the peripheral device 306. In some embodiments, the interface controller 320 is configured to receive a host outgoing serial signal 312 from the one or more processors 304, and determine whether the host outgoing serial signal 312 satisfies a data validation condition. In some embodiments, the interface controller 320 includes one of a field programmable gate array (FPGA) and a complex programmable logic device (CPLD). More specifically, the FPGA is integrated circuit that can be configured after manufacturing, and includes an array of programmable logic blocks that can be reconfigured to perform specific tasks. The FPGA may be customized or adapted in a server system of data centers (e.g., configured to implement high-performance computing and artificial intelligence or machine learning workloads). In some embodiments, the CPLD is a type of programmable logic device that offers a balance between flexibility of the FPGA and simplicity of smaller programmable devices. The CPLD is coupled to the signal output interface 302 and configured to enable one or more control-oriented tasks, such as interfacing and managing basic digital functions. The CPLD includes programmable logic blocks and interconnects, and applies non-volatile memory to retain configuration even after power is turned off. In an example, the CPLD includes one of a glue logic a state machine.

An example of the first controller 314 is a baseboard management controller (BMC), which is a specialized microcontroller embedded in a server's motherboard that enables remote management and monitoring of the server 120, independent of an operating system of the server 120. The BMC is configured for out-of-band management including, but not limited to, monitoring system health, viewing hardware status (temperature, fan speeds, power supply), and even performing remote diagnostics, firmware updates, and server reboots. In some situations, the BMC is applied when the server 120 is unresponsive or the operating system has crashed. In some embodiments, the server 120 is applied in data centers and enterprise environments, and the BMC is applied in the server 120 to control downtime and enable remote management. In some embodiments, the interface controller 320 receives a host outgoing serial signal 312 from the first controller 314 (e.g., BMC), and determines whether the host outgoing serial signal 312 satisfies a data validation condition.

In some implementations of this application, the interface controller 320 receives a first clock signal 316, determines a low cycle length of the first clock signal 316, and dynamically determines a duty cycle of a second clock signal 318 based on the low cycle length of the first clock signal 316, and generates the second clock signal 318 having the duty cycle. The second clock signal 318 is provided to the peripheral device 306 and applied to recover host data from a periphery outgoing serial signal 308 and serialize periphery data returned to the host processor 330. Further, in some embodiments, the interface controller 320 includes, or is coupled to, a non-volatile memory 322 storing one or more of: an outgoing delay 324, an incoming delay 326, and a sampling tolerance time 328. The interface controller 320 extracts at least one of the outgoing delay 324, the incoming delay 326, and the sampling tolerance time 328 for use in determination of the duty cycle of the second clock signal 318. In other words, the at least one of the outgoing delay 324, the incoming delay 326, and the sampling tolerance time 328 may be pre-calibrated and stored as specifications for the electronic device 300, and do not need to be measured every time during the course of controlling the duty cycle of the second clock signal 318.

FIG. 3B is a temporal diagram of a set of sample signals 350 including a first clock signal 316, a host outgoing serial signal 312, and a periphery incoming serial signal 310, in accordance with some embodiments. The electronic device 300 is electrically coupled to a peripheral device 306, and sends a first clock signal 316 and a host outgoing serial signal 312 carrying host data (also called first serial data) to the peripheral device 306 by way of the interface controller 320. The interface controller 320 may output a second clock signal 318 and the outgoing serial signal 308 based on the first clock signal 316 and the host outgoing serial signal 312. After receiving the signals 308 and 318 from the serial output interface 302, the peripheral device 306 extracts the host data from the outgoing serial signal 308 based on the second clock signal 318, and generates periphery data (e.g., based on the extracted host data). The peripheral device 306 further generates, and returns to the electronic device 300, the periphery incoming serial signal 310 carrying the periphery data. The interface controller 320 receives the periphery incoming serial signal 310 via the serial output interface 302, and generates a host incoming serial signal 332 carrying peripheral data. The host incoming serial signal 332 has an incoming delay 326 with respect to the periphery incoming serial signal 310.

In some embodiments, one of the processor(s) 304 and the first controller 314 acts as the host processor 330 to issue the first clocks signal 316 and the host outgoing serial signal 312 and receive the host incoming serial signal 332. From a host perspective, the host data are extracted from rising edges of the host outgoing serial signal 312, and the peripheral data are written into the host incoming serial signal 332 near falling edges of the first clock signal 316, allowing the peripheral data to be extracted from the host incoming serial signal 332 at the rising edges of the first clock signal 316. Alternatively, in some embodiments not shown, the host data are extracted from falling edges of the host outgoing serial signal 312, and the peripheral data are written into the host incoming serial signal 332 near rising edges of the first clock signal 316, allowing the peripheral data to be extracted from the host incoming serial signal 332 at the falling edges of the first clock signal 316.

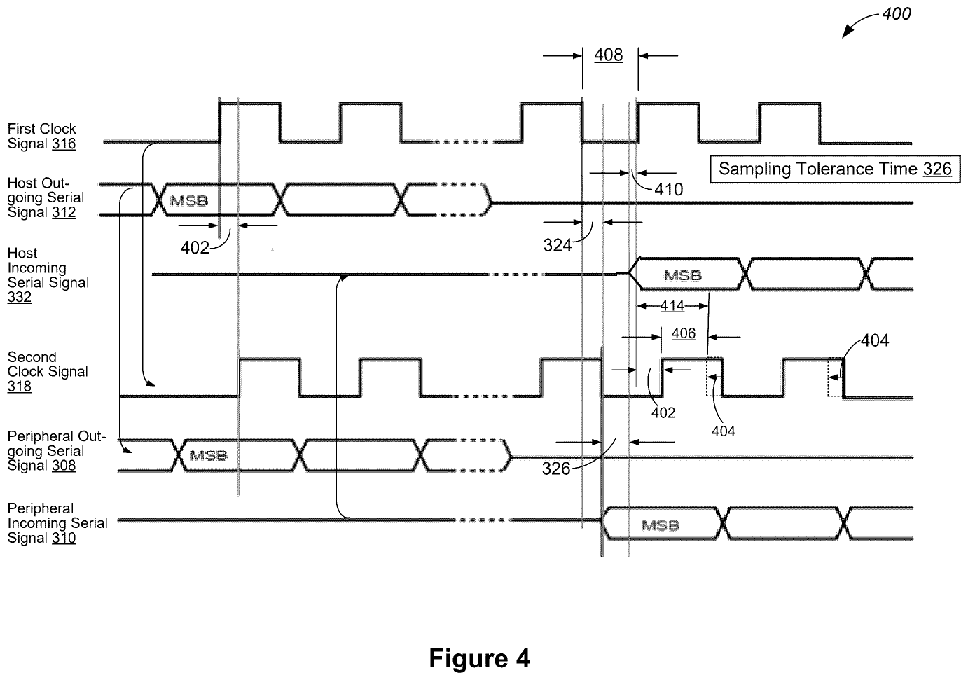

FIG. 4 is a temporal diagram of a plurality of example signals 400 measured at an output of a host processor 330 or a first controller 314 of an electronic device 300 and an input of a peripheral device 306, in accordance with some embodiments. The electronic device 300 includes an interface controller 320 and a serial output interface 302, and is coupled to the peripheral device 306 via the serial output interface 302. The electronic device 300 is configured to provide a second clock signal 318 and a periphery outgoing serial signal 308 to the peripheral device 306 and receive a periphery incoming serial signal 310 from the peripheral device 306.

In some embodiments, one of the processor 304 and the first controller 314 acts as a host processor 330 (FIG. 3A). The host processor 330 generates the first clock signal 316, and the interface controller 320 receives the first clock signal 316 and generates the second clock signal 318. A rising edge of the second clock signal 318 has a rising edge delay 402 with respect to a rising edge of the first clock signal 316. In some embodiments, a falling edge of the second clock signal 318 has an outgoing delay 324 (e.g., a falling edge delay) with respect to a falling edge of the first clock signal 316. In an example, the falling edge of the second clock signal 318 is subsequent to the falling edge of the first clock signal 316, and not adjusted by the interface controller 320. In another example, the falling edge of the second clock signal 318 is subsequent to the falling edge of the first clock signal 316, and adjusted by the interface controller 320 to be closer to the falling edge of the first clock signal 316. In yet another example, the falling edge of the second clock signal 318 is generated after the rising edge of the second clock signal 318, independently of whether the interface controller 320 receives the falling edge of the first clock signal 316. The falling edge of the second clock signal 318 may occur prior to, or at the same time with, the falling edge of the first clock signal 316.

In some embodiments, the host processor 330 generates, and sends to the peripheral device 306, a host outgoing serial signal 312 carrying host data. The interface controller 320 generates a periphery outgoing serial signal 308 based on the host outgoing serial signal 312. After receiving the signals 308 and 318, the peripheral device 306 extracts the host data from the outgoing serial signal 308 based on the second clock signal 318.

In some embodiments, the peripheral device 306 generates, and returns to the host processor 330, a periphery incoming serial signal 310 carrying periphery data. In some embodiments, the peripheral device 306 generates the periphery incoming serial signal 310 carrying periphery data based on the falling edges of the second clock signal 318. The interface controller 320 receives the periphery incoming serial signal 310 and generates a host incoming serial signal 332 carrying the peripheral data. The host incoming serial signal 332 has an incoming delay 326 with respect to the periphery incoming serial signal 310. In some embodiments, the host processor 330 extracts the periphery data from the host incoming serial signal 332 based on the rising edges of the first clock signal 316.

Referring to FIG. 4, in some embodiments, signal read operations occur at rising edges of the first clock signal 316 or the second clock signal 318, and signal write operations occur at falling edges of the first clock signal 316 or the second clock signal 318. The first clock signal 316 has a low cycle length 408 of the first clock signal 316. The low cycle length 408 is a sum of the outgoing delay 324, the incoming delay 326, and a temporal margin 410. The temporal margin 410 measures a temporal distance between an edge of the host incoming serial signal 332 and a rising edge of the first clock signal 316. In some embodiments, the temporal margin 410 is required to be equal to or greater than a sampling tolerance time 328 that defines a temporal length limit between edges of the host incoming serial signal 332 and the first clock signal 316. In some situations, the temporal margin 410 is less than the sampling tolerance time 328. Edges of the host incoming serial signal 332 and the first clock signal 316 are close, such that the host processor 330 fails to extract the periphery data from the host incoming serial signal 332. Conversely, in some situations, the temporal margin 410 is greater than or equal to the sampling tolerance time 328, the host processor 330 can extract the periphery data from the host incoming serial signal 332 properly.

In some embodiments not shown in FIG. 4, signal read operations occur at falling edges of the first clock signal 316 or the second clock signal 318, and signal write operations occur at rising edges of the first clock signal 316 or the second clock signal 318. The first clock signal 316 has a high cycle length of the first clock signal 316. The high cycle length is a sum of the rising edge delay 402, the incoming delay 326, and a temporal margin. The temporal margin measures a temporal distance between an edge of the host incoming serial signal 332 and a falling edge of the first clock signal 316. In some embodiments, the temporal margin 410 is required to be equal to or greater than an associated sampling tolerance time 328 to extract the periphery data from the host incoming serial signal 332 properly.

In various embodiments of this application, a duty cycle of the second clock signal 318 is dynamically determined based on the low cycle length 408 of the first clock signal 316. In an example, the first clock signal 316 has a known duty cycle, and the low cycle length 408 of the first clock signal 316 may be determined based on a period of the first clock signal 316. Further, in some embodiments, the temporal margin 410 is determined based on the low cycle length 408, the outgoing delay 324, and the incoming delay 326, and compared with the sampling tolerance time 328 to determine whether and how much an edge of the second clock signal 318 associated with generation of the periphery incoming serial signal 310 needs to be moved. A temporal change of the edge of the second clock signal 318 represents a change of the duty cycle of the second clock signal 318.

FIG. 5 is a temporal diagram illustrating a plurality of example compensation schemes 500 associated with a duty cycle of a second clock signal 318, in accordance with some embodiments. An interface controller 320 receives a first clock signal 316 and determines a low cycle length 408 of the first clock signal 316. The interface controller 320 dynamically determines a duty cycle of a second clock signal 318 based on the low cycle length 408 of the first clock signal 316, and generates the second clock signal 318 having the duty cycle. In some embodiments, the interface controller 320 determines the low cycle length 408 of the first clock signal 316 by determining a period T and a duty cycle D₁ of the first clock signal 316. The low cycle length 408 of the first clock signal 316 is determined based on the period T and the duty cycle D₁ of the first clock signal 316. For example, the low cycle length 408 of the first clock signal 316 is equal to T×(1−D₁).

Broadly, in some embodiments, the interface controller 320 determines an outgoing delay 324 and an incoming delay 326 of the interface controller 320, and the duty cycle of the second clock signal 318 is determined based on a sum of the outgoing delay 324 and the incoming delay 326 of the interface controller 320. In some embodiments, the interface controller 320 is coupled between a host processor 330 (e.g., one or more processors 304, a first controller 314) and a serial output interface 302 of the electronic device 300. The interface controller 320 determines a sampling tolerance time 328 of the host processor 330 (e.g., one or more processors 304, a first controller 314), and the sampling tolerance time 328 defines a temporal length limit between edges of a host incoming serial signal 332 and the first clock signal 316 of the host processor 330. If the edges of the host incoming serial signal 332 and the first clock signal 316 of the host processor 330 are too close to each other, e.g., within the sampling tolerance time 328, the host processor 330 cannot extract periphery data provided by the peripheral device 306 from the first clock signal 316. The duty cycle of the second clock signal 318 is determined based on the sampling tolerance time 328.

More specifically, in some embodiments, the interface controller 320 determines one or more of: an outgoing delay 324 of the second clock signal 318 with respect to the first clock signal 316, an incoming delay 326 of a host incoming serial signal 332 with respect to a periphery incoming serial signal 310, and a sampling tolerance time 328 of a host processor 330 (e.g., one or more processors 304, a first controller 314). The interface controller 320 is coupled between the host processor 330 and the serial output interface 302, and the sampling tolerance time 328 defines a temporal length limit between edges of the host incoming serial signal 332 and the first clock signal 316 of the host processor 330. Further, in some embodiments, the one or more of the outgoing delay 324, the incoming delay 326, and the sampling tolerance time 328 are extracted from memory 322. Alternatively, in some embodiments, the one or more of the outgoing delay 324, the incoming delay 326, and the sampling tolerance time 328 are determined by the interface controller 320 in real-time.

In some embodiments, the interface controller 320 determines a first difference 502 (e.g., corresponding to the temporal margin 410 in FIG. 4) between the low cycle length 408 of the first clock signal 316 and a sum of the incoming delay 326 and the outgoing delay 324, and further determines whether to change the duty cycle of the second clock signal 318 based on the first difference 502. Further, in some embodiments associated with the host incoming serial signal 332-1, in accordance with a determination that the first difference 502 is equal to or greater than the sampling tolerance time 328 of the host processor 330 (e.g., one or more processors 304, first controller 314), the interface controller 320 maintains the duty cycle of the second clock signal 318 without change. Stated another way, in some situations, a sum of the outgoing delay 324, the sampling tolerance time 328, and the incoming delay 326-1 is less than the low cycle length 408 of the first clock signal 316. The duty cycle of the second clock signal 318 does not need to be adjusted.

Conversely, in some embodiments associated with the host incoming serial signal 332-2, in accordance with a determination that the first difference 502′ is less than the sampling tolerance time 328 of the host processor 330 (e.g., one or more processors 304, first controller 314), the interface controller 320 increases the low cycle length of the second clock signal 318 by a temporal change 404, thereby changing the duty cycle of the second clock signal 318. In an example, the first difference 502′ is negative. In other words, in some situations, a sum of the outgoing delay 324, the sampling tolerance time 328, and the incoming delay 326-2 is greater than the low cycle length 408 of the first clock signal 316. The temporal change 404 is equal to or greater than a second difference of the sum of the outgoing delay 324, the sampling tolerance time 328, and the incoming delay 326 and the low cycle length of the first clock signal 316.

In an example, the temporal change 404 is applied to a falling edge 504 of the second clock signal 318. In some implementations, the falling edge of the second clock signal 318 is generated, after the rising edge of the second clock signal 318 is generated, independently of whether the failing edge of the first clock signal 318 has happened at the host processor 330. The falling edge 504 of the second clock signal 318 may precede or follow the corresponding failing edge 506 of the first clock signal 316.

In some embodiments, the interface controller 320 determines a high temporal width 406 based on the duty cycle of the second clock signal 318, which is dynamically determined based on the low cycle length 408 of the first clock signal 316. The interface controller 320 terminates a high voltage level of the second clock signal 318 in response to termination of the high temporal width 406 measured from a corresponding rising edge of the second clock signal 318. Additionally or alternatively, in some embodiments, the interface controller 320 determines a temporal distance 414 of the falling edge of the second clock signal 318 measured from a rising edge of first clock signal 316, e.g., as a sum of the rising edge delay 402 and the high temporal width 406. The interface controller 320 terminates a high voltage level of the second clock signal 318 in response to termination of the temporal distance 414 measured from a corresponding rising edge of the first clock signal 316.

In some embodiments, the first clock signal 316 has a plurality of rising edges 508. The interface controller 320 receives, from the host processor 330 (e.g., one or more processors 304), a host outgoing serial signal 312 including first serial data (also called host data) jointly with the first clock signal 316, and the host outgoing serial signal 312 is synchronized with the plurality of rising edges 508 of the first clock signal 316. Further, in some embodiments, the first clock signal 316 has a plurality of falling edges 506. The interface controller 320 receives, from a peripheral device 306 (FIG. 3) coupled to the electronic device 300, a periphery incoming serial signal 310, and the host processor 330 (e.g., one or more processors 304) processes second serial data (also called periphery data) in the periphery incoming serial signal 310 based on the plurality of falling edges 506 of the first clock signal 316.

In some embodiments, the serial output interface 302 complies with a high speed data communication protocol, e.g., Universal Serial Bus (USB), Serial Advanced Technology Attachment (SATA), and Peripheral Component Interconnect Express (PCIe). The first clock signal 316 has a baseband frequency, and is applied to exchange data (e.g., in an equalization process) at the baseband frequency for the purposes of establishing data communication between the electronic device 300 and the peripheral device 306 at a high data speed. The high data speed is enabled by a data clock frequency that is greater than the baseband frequency. An example of the baseband frequency is 100 MHz, and examples of the high data speed include, but are not limited to, 5-40 Gigabits per second (Gbps) for USB 3.0 and above, 20 Gbps, 40 Gbps, 1.5-6 Gbps (SATA), and 4-128 Gigabytes per second (GB/s) for PCIe.

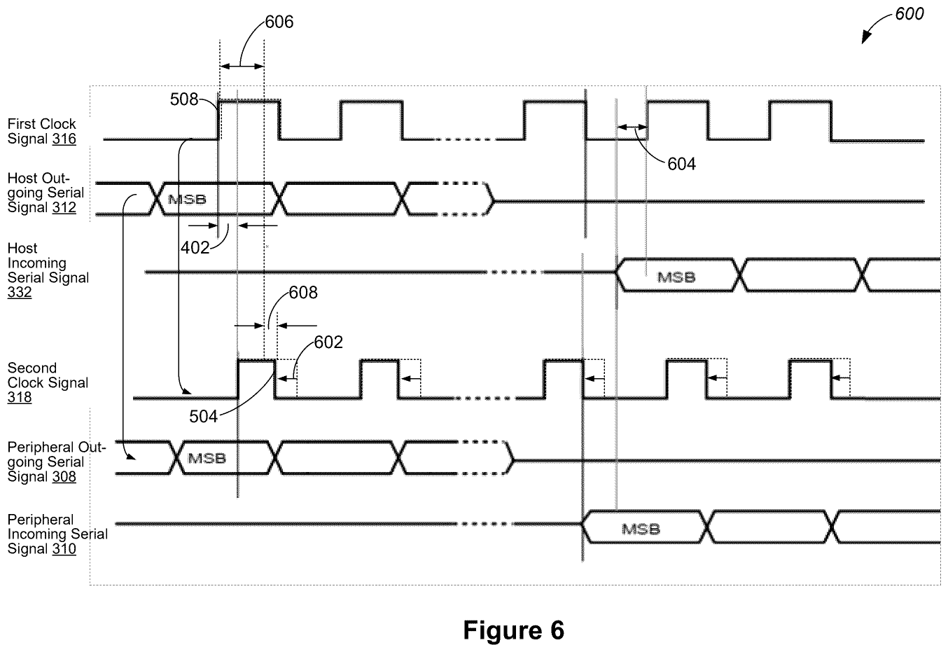

FIG. 6 is a temporal diagram illustrating another example compensation scheme 600 applied to modify a duty cycle of a second clock signal 318, in accordance with some embodiments. An interface controller 320 of an electronic device 300 (FIG. 3) determines a first difference 502′ (FIG. 5) between a low cycle length 408 of a first clock signal 316 and a sum of the incoming delay 326 (e.g., delay 326-2 in FIG. 5) and the outgoing delay 324. In accordance with a determination that the first difference 502′ is less than a sampling tolerance time 328 of a host processor 330 (e.g., one or more processors 304, first controller 314), the interface controller 320 increases the low cycle length of the second clock signal 318 by a temporal change 602, thereby changing a duty cycle of the second clock signal 318. For example, the duty cycle of the second clock signal 318 corresponds to a high cycle length of the second clock signal 318, and is reduced based on the temporal change 602.

In some embodiments, a sum of the outgoing delay 324, the sampling tolerance time 328, and the incoming delay 326-2 is greater than the low cycle length 408 of the first clock signal 316. The temporal change 602 is equal to or greater than a second difference of the sum of the outgoing delay 324, the sampling tolerance time 328, and the incoming delay 326) and the low cycle length 408 of the first clock signal 316. By these means, a temporal length 604 between edges of the host incoming serial signal 332 and the first clock signal 316 of the host processor 330 is greater than the sampling tolerance time 328, and the periphery data can be properly extracted from the host incoming serial signal 332.

In some embodiments, a rising edge of the second clock signal 318 has a rising edge delay 402 with respect to a rising edge 508 of the first clock signal 316. At the rising edge 508 of the first clock signal, the interface controller 320 starts a timeout counter to terminate a high voltage level of the second clock signal 318 after a timeout length 606, and the second clock signal 318 drops to a low voltage level with a timeout delay 608. A combination of the timeout length 606 and the timeout delay 608 results in a temporal distance 414 (FIG. 4) of a falling edge 504 of the second clock signal 318 measured from the rising edge 508 of first clock signal 316. As explained above, the temporal distance 414 is also equal to a sum of the rising edge delay 402 and the high temporal width 406. Stated another way, the duty cycle of the second clock signal 318 is dynamically determined based on the low cycle length 408 of the first clock signal 316, and further applied to derive the timeout length 606. The timeout counter may further control each falling edge 504 of the second clock signal 316 with respect to a respective rising edge 508 of the first clock signal 316 based on the timeout length 606.

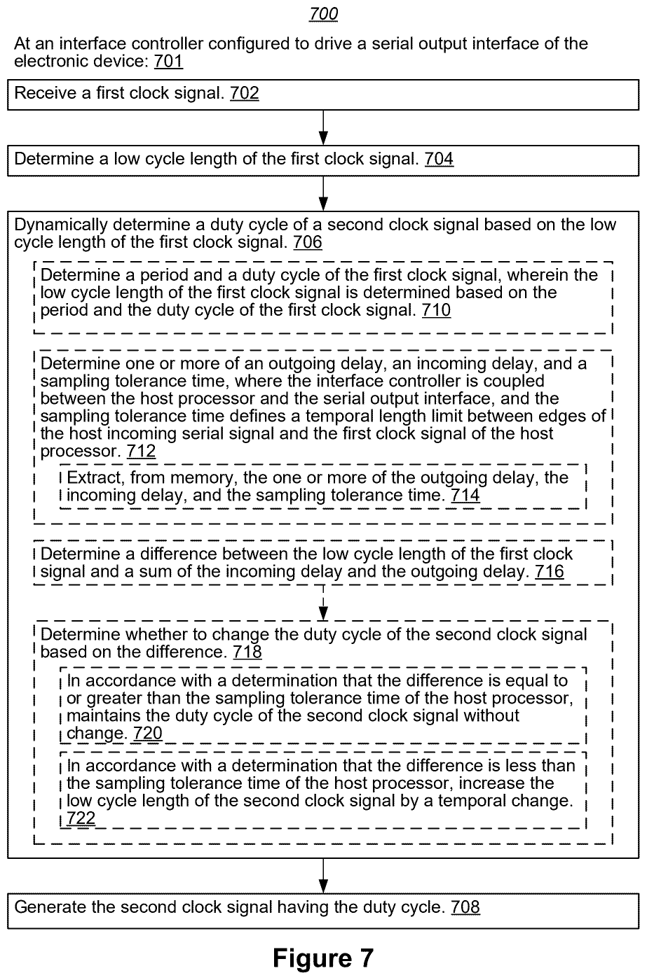

FIG. 7 is a flow diagram of an example method 700 for managing signal timing on a serial output interface 302 of an electronic device 300 (e.g., a server 120 in FIG. 1), in accordance with some embodiments. In some embodiments, the method 700 is implemented at an electronic device 300 having a serial output interface and an interface controller 320. The interface controller 320 is configured to drive the serial output interface of the electronic device 300. More specifically, in some embodiments, the method 700 is implemented (operation 701) at the interface controller 320 of the electronic device 300. The method 700 is, optionally, governed by instructions that are stored in a non-transitory computer readable storage medium and that are executed by the electronic device 300 (e.g., by the interface controller 320). Each of the operations shown in FIG. 7 may correspond to instructions stored in a computer memory or non-transitory computer readable storage medium. The computer readable storage medium may include a magnetic or optical disk storage device, solid state storage devices such as Flash memory, or other non-volatile memory device or devices. The instructions stored on the computer readable storage medium may include one or more of: source code, assembly language code, object code, or other instruction format that is interpreted by the interface controller 320. Some operations in method 700 may be combined and/or the order of some operations may be changed.

The interface controller 320 is configured to drive a serial output interface 302 of the electronic device 300. The interface controller 320 receives (operation 702) a first clock signal 316, determines (operation 704) a low cycle length 408 of the first clock signal 316, dynamically determines (operation 706) a duty cycle of a second clock signal 318 based on the low cycle length 408 of the first clock signal 316, and generates (operation 708) the second clock signal 318 having the duty cycle.

In some embodiments, the interface controller 320 determines an outgoing delay 324 and an incoming delay 326 of the interface controller 320, and the duty cycle of the second clock signal 318 is determined based on a sum of the outgoing delay 324 and the incoming delay 326 of the interface controller 320.

In some embodiments, the interface controller 320 determines a sampling tolerance time 328 of a host processor 330. The interface controller 320 is configured to be coupled between the host processor 330 and the serial output interface 302. The sampling tolerance time 328 defines a temporal length limit between edges of a host incoming serial signal 332 and the first clock signal 316 of the host processor 330. The duty cycle of the second clock signal 318 is determined based on the sampling tolerance time 328.

In some embodiments, when the interface controller 320 determines the low cycle length 408 of the first clock signal 316, the interface controller 320 determines (operation 710) a period T and a duty cycle D₁ of the first clock signal 316. The low cycle length 408 of the first clock signal 316 is determined based on the period and the duty cycle of the first clock signal 316.

In some embodiments, the interface controller 320 determines (operation 712) one or more of an outgoing delay 324 of the second clock signal 318 with respect to the first clock signal 316, an incoming delay 326 of a host incoming serial signal 332 with respect to a periphery incoming serial signal 310, and a sampling tolerance time 328 of a host processor 330. The interface controller 320 is coupled between the host processor 330 and the serial output interface 302, and the sampling tolerance time 328 defines a temporal length limit between edges of the host incoming serial signal 332 and the first clock signal 316 of the host processor 330. Further, in some embodiments, the one or more of the outgoing delay 324, the incoming delay 326, and the sampling tolerance time 328 is extracted (operation 714) from memory 322 (FIG. 3).

In some embodiments, the interface controller 320 determines (operation 716) a first difference 502 between the low cycle length 408 of the first clock signal 316 and a sum of the incoming delay 326 and the outgoing delay 324, and determines (operation 718) whether to change the duty cycle of the second clock signal 318 based on the first difference 502. Additionally, in some embodiments, in accordance with a determination that the first difference 502 is equal to or greater than the sampling tolerance time 328 of the host processor 330, the interface controller 320 maintains (operation 720) the duty cycle of the second clock signal 318 without change. Conversely, in some embodiments, in accordance with a determination that the first difference 502 is less than the sampling tolerance time 328 of the host processor 330, the interface controller 320 increases (operation 722) the low cycle length 408 of the second clock signal 318 by a temporal change 602 (FIG. 6). In some embodiments, the temporal change 602 is equal to or greater than a second difference of a sum of the outgoing delay 324, the sampling tolerance time 328, and the incoming delay 326 and the low cycle length 408 of the first clock signal 316.

In some embodiments, the duty cycle of the second clock signal 318 corresponds to a temporal change 602 of a falling edge of the second clock signal 318, and the temporal change 602 is equal to or greater than a second difference of a sum of the outgoing delay 324, the sampling tolerance time 328, and the incoming delay 326 and the low cycle length 408 of the first clock signal 316.

In some embodiments, the interface controller 320 determines a temporal distance from a rising edge of one of the first clock signal 316 and the second clock signal 318 based on the duty cycle of the second clock signal 318. For example, a high temporal width 406 (FIG. 4) is determined as the temporal distance from the rising edge of the second clock signal 318. In another example, the temporal distance 414 (FIG. 4) is determined from the rising edge of the first clock signal 316. The interface controller 320 generates the second clock signal 318 having the duty cycle by terminating a high voltage level of the second clock signal 318 in response to termination of the temporal distance measured from the rising edge of the one of the first clock signal 316 and the second clock signal 318.

In some embodiments, the first clock signal 316 has a plurality of rising edges 508. The interface controller 320 receives, from a host processor 330 of the electronic device 300, a host outgoing serial signal 312 including first serial data (e.g., host data) jointly with the first clock signal 316. The host outgoing serial signal 312 is synchronized with the plurality of rising edges of the first clock signal 316. Further, in some embodiments, the first clock signal 316 has a plurality of falling edges 506. The interface controller 320 receives an periphery incoming serial signal 310 from a peripheral device coupled to the electronic device 300. The host processor 330 is configured to process second serial data in the periphery incoming serial signal 310 based on the plurality of falling edges of the first clock signal 316.

In some embodiments, the electronic device 300 includes the interface controller 320 and at least one of a central processing unit (CPU) and a baseboard management controller (BMC) 314, and the interface controller 320 receives the first clock signal 316 from the at least one of the CPU and the BMC 314.

In some embodiments, the serial output interface 302 is coupled to a flash memory device, and the second clock signal 318 is provided to the flash memory device.

In some embodiments, the interface controller 320 receives a host outgoing serial signal 312 and determines whether the host outgoing serial signal 312 satisfies a data validation condition.

In some embodiments, the interface controller 320 receives a host outgoing serial signal 312 jointly with the first clock signal 316 from a host processor 330 of the electronic device 300, and a periphery incoming serial signal 310 via the serial output interface 302.

In some embodiments, the interface controller 320 includes one of a Field Programmable Gate Array (FPGA) and a Complex Programmable Logic Device (CPLD).

It should be understood that, in some embodiments, the incoming delay 326 and the outgoing delay 324 are at least partially caused by the interface controller 320, and a distinct controller of the electronic device is applied to implement the method 700 to determine the duty cycle of the second clock signal 318 and control the interface controller 320 to move edges of the second clock signal 318 accordingly, thereby compensating for the delays 324 and 326.

It should be understood that the particular order in which the operations in FIG. 7 have been described are merely exemplary and are not intended to indicate that the described order is the only order in which the operations could be performed. One of ordinary skill in the art would recognize various ways to manage signal timing on a serial data interface as described herein. Additionally, it should be noted that details of other processes described herein with respect to other figures (e.g., FIGS. 1-6) are also applicable in an analogous manner to method 700 described above with respect to FIG. 7. For brevity, these details are not repeated here.

The terminology used in the description of the various described implementations herein is for the purpose of describing particular implementations only and is not intended to be limiting. As used in the description of the various described implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. A method for managing signal timing for an electronic device, comprising:
at an interface controller, wherein the interface controller is configured to drive a serial output interface of the electronic device:
receiving a first clock signal;
determining a low cycle length of the first clock signal;
dynamically determining a duty cycle of a second clock signal based on the low cycle length of the first clock signal; and
generating the second clock signal having the duty cycle.

2. The method of claim 1, further comprising determining an outgoing delay and an incoming delay of the interface controller, and the duty cycle of the second clock signal is determined based on a sum of the outgoing delay and the incoming delay of the interface controller.

3. The method of claim 1, further comprising determining a sampling tolerance time of a host processor, wherein:
the interface controller is configured to be coupled between the host processor and the serial output interface;
the sampling tolerance time defines a temporal length limit between edges of a host incoming serial signal and the first clock signal of the host processor; and
the duty cycle of the second clock signal is determined based on the sampling tolerance time.

4. The method of claim 1, determining the low cycle length of the first clock signal further comprising:
determining a period and a duty cycle of the first clock signal, wherein the low cycle length of the first clock signal is determined based on the period and the duty cycle of the first clock signal.

5. The method of claim 1, further comprising determining one or more of:
an outgoing delay of the second clock signal with respect to the first clock signal;
an incoming delay of a host incoming serial signal with respect to a periphery incoming serial signal; and
a sampling tolerance time of a host processor, the interface controller is coupled between the host processor and the serial output interface, the sampling tolerance time defining a temporal length limit between edges of the host incoming serial signal and the first clock signal of the host processor.

6. The method of claim 5, determining the one or more of the outgoing delay, the incoming delay, and the sampling tolerance time further comprising:
extracting, from memory, the one or more of the outgoing delay, the incoming delay, and the sampling tolerance time.

7. The method of claim 5, further comprising:
determining a first difference between the low cycle length of the first clock signal and a sum of the incoming delay and the outgoing delay; and
determining whether to change the duty cycle of the second clock signal based on the first difference.

8. The method of claim 7, determining the duty cycle of the second clock signal further comprising:
in accordance with a determination that the first difference is equal to or greater than the sampling tolerance time of the host processor, maintaining the duty cycle of the second clock signal without change.

9. The method of claim 7, determining the duty cycle of the second clock signal further comprising:
in accordance with a determination that the first difference is less than the sampling tolerance time of the host processor, increasing the low cycle length of the second clock signal by a temporal change;
wherein the temporal change is equal to or greater than a second difference of a sum of the outgoing delay, the sampling tolerance time, and the incoming delay and the low cycle length of the first clock signal.

10. The method of claim 5, wherein the duty cycle of the second clock signal corresponds to a temporal change of a falling edge of the second clock signal, and the temporal change is equal to or greater than a second difference of a sum of the outgoing delay, the sampling tolerance time, and the incoming delay and the low cycle length of the first clock signal.

11. The method of claim 1, further comprising:
determining a temporal distance from a rising edge of one of the first clock signal and the second clock signal based on the duty cycle of the second clock signal;
wherein generating the second clock signal having the duty cycle further includes terminating a high voltage level of the second clock signal in response to termination of the temporal distance measured from the rising edge of the one of the first clock signal and the second clock signal.

12. The method of claim 1, wherein the first clock signal has a plurality of rising edges, the method further comprising:
receiving, from a host processor of the electronic device, a host outgoing serial signal including first serial data jointly with the first clock signal, wherein the host outgoing serial signal is synchronized with the plurality of rising edges of the first clock signal.

13. The method of claim 12, wherein the first clock signal has a plurality of falling edges, the method further comprising:
receiving, from a peripheral device coupled to the electronic device, an periphery incoming serial signal, wherein the host processor is configured to process second serial data in the periphery incoming serial signal based on the plurality of falling edges of the first clock signal.

14. The method of claim 1, wherein the electronic device includes the interface controller and at least one of a central processing unit (CPU) and a baseboard management controller (BMC), and the interface controller receives the first clock signal from the at least one of the CPU and the BMC.

15. The method of claim 1, wherein the serial output interface is coupled to a flash memory device, and the second clock signal is provided to the flash memory device.

16. The method of claim 1, further comprising receiving a host outgoing serial signal and determining whether the host outgoing serial signal satisfies a data validation condition.

17. The method of claim 1, further comprising:
receiving a host outgoing serial signal jointly with the first clock signal from a host processor of the electronic device; and
receiving a periphery incoming serial signal via the serial output interface.

18. The method of claim 1, wherein the interface controller includes one of a Field Programmable Gate Array (FPGA) and a Complex Programmable Logic Device (CPLD).

19. An electronic device, comprising:
a host processor configured to provide a first clock signal and processing a host incoming serial signal;
an interface controller coupled to the host processor, the interface controller configured to:
receive the first clock signal;
determine a low cycle length of the first clock signal;
dynamically determine a duty cycle of a second clock signal based on the low cycle length of the first clock signal; and
generate the second clock signal having the duty cycle; and
a serial output interface coupled to the interface controller, the serial output interface configured to couple to a peripheral device and provide the second clock signal to the peripheral device.

20. A non-transitory computer-readable storage medium, storing one or more programs for execution by an interface controller, the one or more programs further comprising instructions for:
at the interface controller, wherein the interface controller is configured to drive a serial output interface of an electronic device:
receiving a first clock signal;
determining a low cycle length of the first clock signal;
dynamically determining a duty cycle of a second clock signal based on the low cycle length of the first clock signal; and
generating the second clock signal having the duty cycle.
